(19) United States
(12) Patent Application Publication
(10) Pub. No.: US 2016/0173132 A1
(43) Pub. Date: Jun. 16, 2016

(54) Construction of Structured LDPC Convolutional Codes

(71) Applicant: Alcatel-Lucent USA Inc., Murray Hill, NJ (US)

(72) Inventor: Joon Ho Cho, Holmdel, NJ (US)

(21) Appl. No.: 14/565,480

(22) Filed: Dec. 10, 2014

(51) Int. Cl. H03M 13/11; H03M 13/00

(52) U.S. Cl. CPC H03M 13/1154; H03M 13/616

(57) ABSTRACT

Protograph construction methods for generating convolutional LDPC code matrices are disclosed in which multi-equation problems of girth maximization are reduced or replaced using other techniques including (with limitation): finding base matrices with a unique set of non-repeating distance parameters, finding the minimum largest such distance parameter among solution-set matrices, and quasi-cyclic lifting of the generated convolutional LDPC code matrix. 4-cycles and select (avoidable) 6-cycles are thereby removed from the resulting convolutional LDPC code matrix, thereby resulting in significant performance gains.

### BACKGROUND

1. Field of the Invention

The present invention relates to low-density parity-check (LDPC) convolutional codes and, more specifically but not exclusively, to a protograph-based construction method for LDPC convolutional codes.

2. Description of the Related Art

The following discussion outlines some background to aid in comprehending the nature and operation of the various embodiments of the disclosure. This section introduces aspects that may be helpful for a better understanding of the invention(s). Accordingly, the statements of this section are to be read in this light and are not intended to be understood as admissions or other statements about what is and/or what is not prior art.

The present discussion presupposes a general working knowledge of low-density parity-check coding schemes, which may be found, inter alia, addressed among the following documents, which are incorporated herein by reference in their entirety.

U.S. Patent Application Publication No. 2012/0240001 describes a method to construct a family of LDPC codes. The method includes identifying a code rate for an LDPC code in the family, identifying a protograph for the LDPC code, and constructing a base matrix for the LDPC code. The base matrix is constructed by replacing each 0 in the protograph with 1, selecting a corresponding value for an absolute shift for each 1 in the protograph based on constraining a number of relative shifts per column of the LDPC code to unity and increasing a size of a smallest cycle in a graph of the LDPC code, and replacing each 1 in the protograph with the corresponding value.

U.S. Patent Application Publication No. 2012/0131409 describes digital communication coding methods that generate certain types of LDPC codes built from protographs. A first method creates protographs having the linear minimum distance property and comprising at least one variable node with degree less than 3. A second method creates families of protographs of different rates, all structurally identical for all rates except for a rate-dependent designation of certain variable nodes as transmitted or non-transmitted. A third method creates families of protographs of different rates, all structurally identical for all rates except for a rate-dependent designation of the status of certain variable nodes as non-transmitted or set to zero. LDPC codes built from the protographs created by these methods can simultaneously have low error floors and better iterative decoding thresholds.

U.S. Pat. No. 8,689,083 discloses digital communication coding methods resulting in rate-compatible LDPC codes built from protographs. Described digital coding methods start with a desired code rate and a selection of the numbers of variable nodes and check nodes to be used in the protograph. Constraints are set to satisfy a linear minimum distance growth property for the protograph. All possible edges in the graph are enumerated, and the protograph with the best iterative decoding threshold is selected. Protographs designed in this manner are used in decode and forward relay channels.

### 1. LDPC Convolutional Codes

A time-varying LDPC convolutional code can be defined as the set of infinite sequences v=[ . . . , v₀, v₁, . . . , vₜ, . . . ] satisfying the equation vH^{T}=0, where vₜ=[vₜ⁽¹⁾, . . . , vₜ^{(c)}] with vₜ^{(•)} ε{0, 1}, and where H^{T}:

$${H}^{T} = [ \begin{matrix}⋱ & & ⋱ & & & & \\ {H}_{0}^{T} ( 0 ) & … & {H}_{{m}_{s}}^{T} ( {m}_{s} ) & & & & \\ & ⋱ & & ⋱ & & & \\ & & {H}_{0}^{T} ( {m}_{s} ) & … & {H}_{{m}_{s}}^{T} ( 2 {m}_{s} ) & & \\ & & ⋱ & & ⋱ & & \\ & & & {H}_{0}^{T} ( t ) & … & {H}_{{m}_{s}}^{T} ( t + {m}_{s} ) & \\ & & & ⋱ & … & ⋱ & ⋱\end{matrix} ] \qquad ( 1 )$$

is a (time-varying) infinite transposed parity-check matrix, also called a syndrome former. This LDPC convolutional code will have an asymptotic code rate of R=b/c, where c is the length of vₜ, and where b is the number of informational bits within vₜ (and, by implication, where c−b is the number of parity-check bits). The elements Hᵢ^{T}(t), i=0, 1, . . . , mₛ, are binary c×(c−b) submatrices defined as:

$${H}_{i}^{T} ( t ) = [ \begin{matrix}{h}_{i}^{( 1 , 1 )} ( t ) & … & {h}_{i}^{( 1 , c - b )} ( t ) \\ ⋮ & ⋱ & ⋮ \\ {h}_{i}^{( c , 1 )} ( t ) & … & {h}_{i}^{( c , c - b )} ( t )\end{matrix} ] . \qquad ( 2 )$$

The parameter mₛ, called the syndrome former memory, and the associated constraint length vₛ=(mₛ+1)·c determine the span of the nonzero diagonal region of H^{T}. That is, the constraint length provides a maximum value for the length between two nonzero entries in each row. If the syndrome former H^{T} has exactly J ones in every row and K ones in every column, then the code is called (J,K)-regular.

### 2. Protograph Codes

A small bipartite graph is called a protograph. A simple protograph with three variable nodes and two check nodes, and the corresponding biadjacency matrix, which is called the base matrix, are depicted in FIG. 1.

The derived graph is constructed by replicating the protograph many times and then permuting the base graph as illustrated in FIG. 2, where the permute operation is performed only within each set of edge copies.

The parity-check matrix of an example derived graph of the protograph of FIG. 1 is shown below:

$$H = [ \begin{matrix}1 & 0 & 1 & 1 & 0 & 0 & 0 & 0 & 0 \\ 1 & 1 & 0 & 0 & 1 & 0 & 0 & 0 & 0 \\ 0 & 1 & 1 & 0 & 0 & 1 & 0 & 0 & 0 \\ 0 & 0 & 0 & 0 & 1 & 0 & 1 & 0 & 0 \\ 0 & 0 & 0 & 0 & 0 & 1 & 0 & 1 & 0 \\ 0 & 0 & 0 & 1 & 0 & 0 & 0 & 0 & 1\end{matrix} ] \qquad ( 3 )$$

It is often said that the protograph is lifted to create the derived graph.

### 3. Circulant and Permutation Matrices

A circulant matrix is a square matrix with each successive row right-shifted circularly one position relative to the row above. A circulant matrix therefore can be entirely described by a single row or column. A permutation matrix is a square matrix of ones and zeros, such that the sum of each row is one, and the sum of each column is one. A cyclic permutation matrix is a matrix that is both a permutation matrix and a circulant matrix. Non-limiting examples of (a) circulant, (b) permutation, and (c) cyclic permutation matrices are respectively shown in FIG. 3.

4. LDPC Convolutional Codes from Fully Connected Protographs

One of the best existing solutions to construct a good LDPC convolutional code is protograph-based construction, which commences by letting a=gcd(J, K) denote the greatest common divisor of J and K. Then, there exist positive integers J′ and K′ such that i=aJ′, K=aK′, and gcd(J′, K′)=1. Consider a syndrome former H^{T} with syndrome former memory mₛ=a−1. The submatrices Hᵢ^{T}(t), i=0, 1, . . . , mₛ, consist of K′×J′ permutation matrices:

$${H}_{i}^{T} ( t ) = [ \begin{matrix}{P}_{i}^{( 0 , 0 )} ( t ) & {P}_{i}^{( 0 , 1 )} ( t ) & … & {P}_{i}^{( 0 , {J}^{′} - 1 )} ( t ) \\ {P}_{i}^{( 1 , 0 )} ( t ) & {P}_{i}^{( 1 , 1 )} ( t ) & … & {P}_{i}^{( 1 , {J}^{′} - 1 )} ( t ) \\ ⋮ & ⋮ & ⋱ & ⋮ \\ {P}_{i}^{( {K}^{′} - 1 , 0 )} ( t ) & {P}_{i}^{( {K}^{′} - 1 , 1 )} ( t ) & … & {P}_{i}^{( {K}^{′} - 1 , {J}^{′} - 1 )} ( t )\end{matrix} ] , \qquad ( 4 )$$

where Pᵢ^{(k,j)}(t), k=0, 1, . . . , K′−1, j=0, 1, . . . , J′−1 is an M×M permutation matrix. Equivalently, Hᵢ^{T}(t) is a c×(c−b) matrix with c=K′M and b=(K′−J′)M. By construction, H^{T} is the syndrome former of a (J, K)-regular LDPC convolutional code.

The LDPC convolutional code Hᵢ^{T}(t) constructed by Eq. (4) can be represented by a protograph codes with the base matrices:

$${B}_{[ - ∞ , ∞ ]} = [ \begin{matrix}⋱ & & ⋱ & & \\ {B}_{{m}_{s}} & … & {B}_{0} & & \\ & ⋱ & & ⋱ & \\ & & {B}_{{m}_{s}} & … & {B}_{0} \\ & & ⋱ & & ⋱\end{matrix} ] , \qquad ( 5 )$$

where Bᵢ,i=0, . . . , mₛ, are K′×J′ identical component base matrices with all entries equal to 1. As a simple example, a (3, 6) LDPC code can be represented by the base matrix:

$$B = [ \begin{matrix}1 & 1 & 1 & 1 & 1 & 1 \\ 1 & 1 & 1 & 1 & 1 & 1 \\ 1 & 1 & 1 & 1 & 1 & 1\end{matrix} ] . \qquad ( 6 )$$

The corresponding LDPC convolutional code Hᵢ^{T}(t) with the component base matrices B₀=B₁=B₂=[1 1] is:

$${B}_{[ - ∞ , ∞ ]} = [ \begin{matrix}⋱ & & & & & & & \\ & 1 & 1 & & & & & \\ & 1 & 1 & 1 & 1 & & & \\ & 1 & 1 & 1 & 1 & 1 & 1 & \\ & & & 1 & 1 & 1 & 1 & \\ & & & & & 1 & 1 & \\ & & & & & & & ⋱\end{matrix} ] . \qquad ( 7 )$$

For a binary erasure channel (BEC), the density evolution threshold ε*, i.e., the maximum value of the erasure probability for error-free decoding, for the code of Eq. (7) is 0.488. The Shannon limit is equal to εₛₕ=1−R=0.5.

### 5. AR4JA-Based LDPC Convolutional Codes

The protograph of a rate-½ accumulate-repeat-by-4-jagged-accumulate (AR4JA) code shown in FIG. 4 has a base matrix of:

$$B = [ \begin{matrix}1 & 2 & 0 & 0 & 0 \\ 0 & 3 & 1 & 1 & 1 \\ 0 & 1 & 2 & 1 & 2\end{matrix} ] , \qquad ( 8 )$$

where the variable nodes corresponding to the second column are punctured. Edge spreading can be used to obtain the following two component base matrices:

$${B}_{0} = [ \begin{matrix}1 & 1 & 0 & 0 & 0 \\ 0 & 1 & 1 & 0 & 0 \\ 0 & 0 & 0 & 1 & 1\end{matrix} ] , {B}_{1} = [ \begin{matrix}0 & 1 & 0 & 0 & 0 \\ 0 & 2 & 0 & 1 & 1 \\ 0 & 0 & 2 & 0 & 1\end{matrix} ] . \qquad ( 9 )$$

The resulting convolutional protograph code is shown in FIG. 5. For BEC, the threshold ε* of this code is 0.4996, which is very close to the Shannon limit εₛₕ=1−R=0.5.

### SUMMARY

Various embodiments provide computer-implemented methods for generating a convolutional LDPC code matrix, e.g., for use in an LDPC encoding scheme.

One embodiment provides a computer-implemented method for generating a convolutional LDPC code matrix for use in an LDPC coding scheme. According to the claimed method, (a) a base matrix is generated by constraining the base matrix to have a set of distinct distance parameters in which no distance parameter is repeated, (b) a convolutional protomatrix is generated based on the base matrix, and (c) the convolutional protomatrix is lifted to generate the convolutional LDPC code matrix.

### BRIEF DESCRIPTION OF THE DRAWINGS

Other embodiments will become more fully apparent from the following detailed description, the appended claims, and the accompanying drawings in which like reference numerals identify similar or identical elements. It is intended that the embodiments and figures disclosed herein are to be considered illustrative rather than restrictive. In drawings that illustrate non-limiting embodiments:

FIG. 1 illustrates an example protograph and its corresponding biadjacency matrix;

FIG. 2 illustrates an example copy-and-permute operation of the example protograph of FIG. 1;

FIG. 3 provides examples of (a) circulant, (b) permutation, and (c) cyclic permutation matrices;

FIG. 4 illustrates an example accumulate-repeat-by-4-jagged accumulate (AR4JA) protograph and its corresponding biadjacency matrix;

FIG. 5 illustrates an example copy-and-permute operation of the example AR4JA protograph of FIG. 4;

FIG. 6 illustrates a 4-cycle existing in an example base matrix;

FIG. 7 provides an example base matrix with a distinct set of unique distance parameters;

FIG. 8 provides an example distance-parameter matrix corresponding to the example base matrix of FIG. 7;

FIG. 9 illustrates an example case of an avoidable 6-cycle in a base matrix;

FIG. 10 illustrates an example case of an unavoidable 6-cycle in a base matrix;

FIG. 11 illustrates the quasi-cyclic lifting of a base matrix;

FIG. 12 illustrates an example avoidable 6-cycle from a convolutional lifting matrix A_{[-∞,∞]};

FIG. 13 provides a flow chart diagram of a method for generating a convolutional LDPC code matrix for use in an LDPC encoding scheme;

FIG. 14 provides a schematic diagram for a general-purpose computer upon which methods of the disclosed invention may be run;

FIG. 15A illustrates the emergence of unavoidable 6-cycles within a code lifting scheme when periodic shifting is not utilized;

FIG. 15B illustrates the removal of “unavoidable” 6-cycles within a code lifting scheme when periodic shifting is utilized;

FIG. 16 illustrates the derivation of a row-defining vector aᵣ used in the construction of an LDPC decoder utilizing an optimized LDPC convolutional code; and

FIG. 17 provides a component-level block diagram for a signal-processing system-implemented LDPC coding scheme that utilizes the optimized LDPC convolutional codes generated by the methods of the present invention.

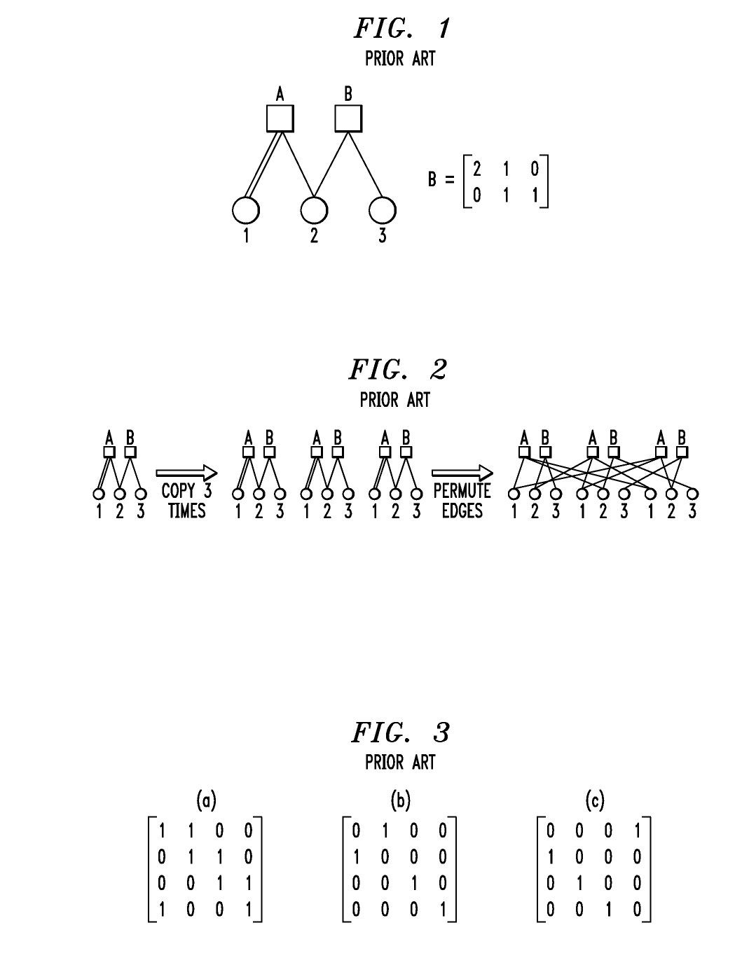

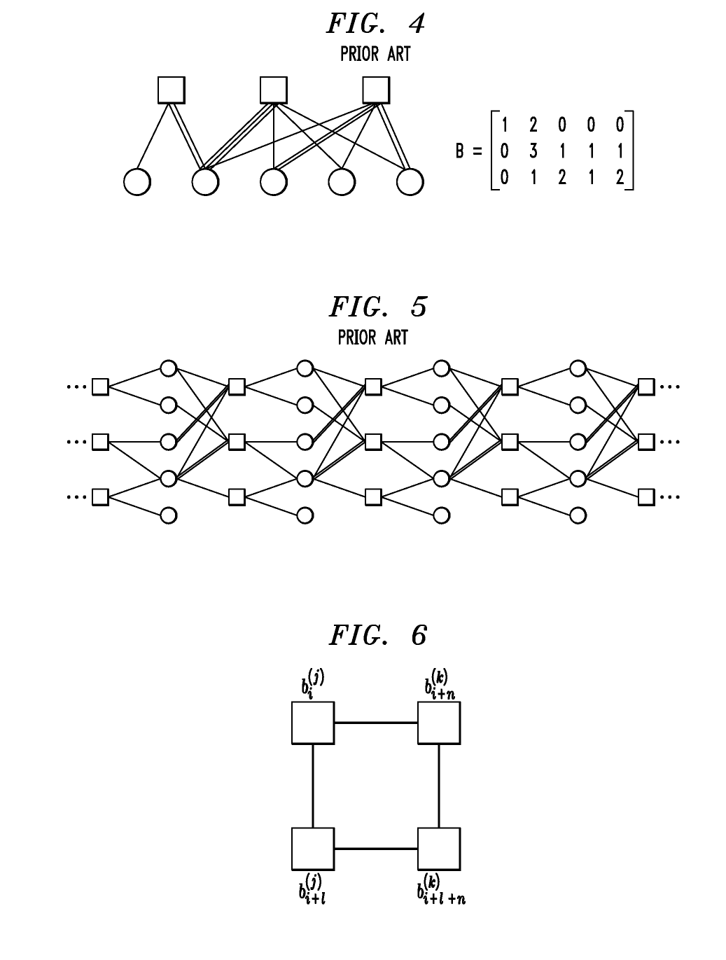

### DETAILED DESCRIPTION

It has been revealed that, with the example code construction method shown in Section 4 above, arbitrarily chosen protographs provide a relatively good threshold. The base matrix of the AR4JA code, shown in Section 5, has a large minimum distance growth rate of the code ensemble for a low error floor, as well as a good density evolution threshold for good waterfall performance. Therefore, the AR4JA-type construction of the base matrices seems promising to derive good LDPC convolutional codes. However, the design routine is mainly intended for block codes, and there is no constructive algorithm. Instead a heuristic is needed to optimize and select the protographs. Furthermore, even if a good base matrix is found, the subsequent copy-and-permute operations need to be optimized. That is, the permutation matrices Pᵢ^{(k,j)}(t) in Eq. (4) should be optimized to derive a particularly good instance of the code ensemble eventually. If the goal is to obtain an extremely low error floor after decoding, e.g., a bit error ratio (BER) of 10⁻¹⁵, then the independent optimization processes for the base and lifting (permutation) matrices may yield a huge lifting factor M, which is defined as the size of the permutation matrices Pᵢ^{(k,j)}(t). This leads to a high implementation cost for the derived code.

The present disclosure follows the existing two-step approach to construct LDPC convolutional codes, which is well-suited to the convolutional decoding process. Given the structural constraint, a girth constraint is set for the base graphs, and the base graphs that have the shortest constraint length are found among all graphs satisfying the girth constraint. Once the base graphs are found, LDPC convolutional codes are derived by periodic quasi-cyclic lifting; i.e., only cyclic permutation matrices are used for lifting, and the permutation matrices are periodically repeated in the time domain such that the derived LDPC codes have much larger girth than the base graphs. By limiting the structure of base graphs and permutation matrices as aforementioned, the derived LDPC convolutional codes can be implemented at a relatively low cost while providing excellent error performance due to their large girth.

Disclosed herein is a method to construct girth-6 protographs that produce the shortest constraint length on the convolutional structure. A stringent structural constraint is imposed on the protographs such that the decoder architecture is greatly simplified. Then, given the structural constraint, finding the girth-6 protographs having the shortest constraint length is reduced to an algebraic problem. With this transformation of the problem, girth-6 protographs can be created in a constructive way, from which can be derived good LDPC convolutional codes—e.g., by using periodic quasi-cyclic lifting and/or the like-in accordance with the discussion that follows.

### 1. Construction of Base Graphs

An assignment of b=c−1 is made for the asymptotic code rate R=b/c. The base LDPC convolutional code is defined by a time-invariant matrix, as represented in Eq. (10):

$${B}_{[ - ∞ , ∞ ]} = [ \begin{matrix}⋱ & {b}_{0} & & & \\ & ⋮ & ⋱ & & \\ ⋱ & {b}_{{m}_{s}} & & {b}_{0} & ⋱ \\ & & ⋱ & ⋮ & \\ & & & {b}_{{m}_{s}} & ⋱\end{matrix} ] , \qquad ( 10 )$$

where the elements bᵢ, i=0, 1, . . . , mₛ, are binary vectors of length c, namely:

bᵢ=[bᵢ⁽¹⁾, . . . ,bᵢ^{(c)}]. (11)

Two constraints for this code can be identified in accordance with the following discussion.

Constraint 1: Binary Symbol Constraint

bᵢ^{(j)}ε{0,1} (12)

for i=0, 1, . . . , mₛ and for j=1, . . . , c. That is, all elements of bᵢ^{(j)} are either a “1” or a “0.”

Constraint 2: Degree Constraint

For each j=1, . . . , c,

$${\sum }_{0 \leq i \leq {m}_{s}} {b}_{i}^{( j )} = {d}_{v}^{( j )} , \qquad ( 13 )$$

where dᵥ^{(j)} are the column degrees of the code. That is, each column j contains dᵥ^{(j)} instances of unity, with all of the other entries being 0. The row degree (i.e., number of instances of unity in each row) is calculated as Σ_{1≦j≦c}dᵥ^{(j)}=d_{c}. If dᵥ^{(j)} are identical for all j=1, . . . , c, (i.e., dᵥ^{(j)}=dᵥ for all j), then the code is variable-regular; otherwise, the code is variable-irregular. Particular embodiments may utilize variable-regular codes with a constant column degree dᵥ. Particular other embodiments may utilize variable-irregular codes with potentially differing column degrees dᵥ^{(j)} for each column j. Note that the check node degree d_{c} of this code is regular and obtained by Eq. (14) as follows:

$${\sum }_{0 \leq i \leq {m}_{s}} {\sum }_{1 \leq j \leq c} {b}_{i}^{( j )} = {d}_{c} , \qquad ( 14 )$$

The rate of the code (and thus its overhead) is given by the relationship between variable and check-node degree—e.g., for a regular code, the rate amounts to R=1−dᵥ/d_{c}.

If the base matrix is defined as B=[b₀^{T}, . . . , bₘ_{ₛ}^{T}]^{T}, then the code B_{[-∞,∞]} is constructed by repeatedly shifting B toward the lower-right direction by one row and c columns (see Eq. 10).

A 4-cycle appears in the code whenever bᵢ^{(j)}=bᵢ₊ₗ^{(j)}=bᵢ₊ₙ^{(k)}=bᵢ₊ₗ₊ₙ^{(k)}=1 holds for any integers i, j, and k satisfying 0≦i≦mₛ−1 and 1≦j<k≦c, and for any integers l and n satisfying 1≦l+n≦mₛ−1 (see FIG. 6). Therefore, a condition can be found to remove all 4-cycles in the code, referred to as “the girth-6 condition”-namely:

bᵢ^{(j)}+bᵢ₊ₗ^{(j)}+bᵢ₊ₙ^{(k)}+bᵢ₊ₗ₊ₙ^{(k)}≦3 (15)

for any j, k, and l defined above. This condition can be simplified to bᵢ^{(j)}+bᵢ₊ₗ^{(j)}+bᵢ^{(k)}+bᵢ₊ₗ^{(k)}≦3 for 1≦l≦mₛ−i, if Theorem 1 is applied, which will be presented in the following section. A condition to remove all 6-cycles (i.e., “the girth-8 condition”) can be derived in a similar manner to the above girth-6 condition.

An objective is to find the optimal bit allocation for the vectors bᵢ such that the syndrome former memory mₛ is minimized while a girth of at least g is obtained for the base code B_{[-∞,∞]}. This objective can be fulfilled by assigning an arbitrary (large) number to mₛ, seeing if there exists a solution to the set of equations, i.e., Eqs. 12, 13, and 15 for the assigned mₛ, and repeating this process with a decremented mₛ until no solution exists.

### Example 1

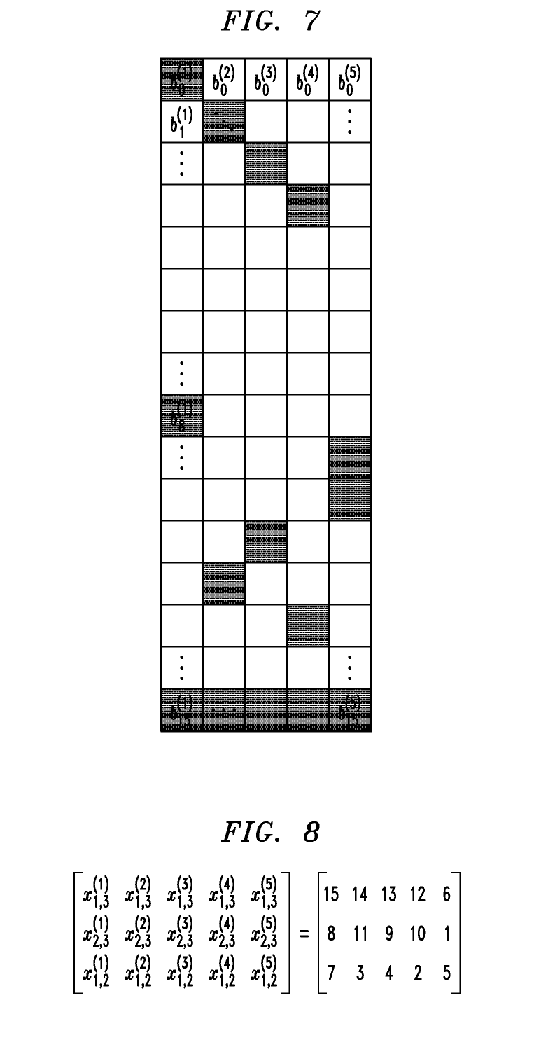

It is possible that there are multiple optimal solutions bᵢ having the same minimal syndrome former memory mₛ for a given girth. Example optimal solutions for the parameters c=5, b=4, R=b/c=0.8, dᵥ⁽¹⁾=dᵥ⁽²⁾=dᵥ⁽³⁾=dᵥ⁽⁴⁾=dᵥ⁽⁵⁾=3, d_{c}=15, and g=6 provide the shortest syndrome former memory mₛ=15. One of them is depicted in FIG. 7, where the white and black squares indicate bit values 0 and 1, respectively, for bᵢ^{(j)}.

### 2. Alternative Optimal Construction of Base Graphs

Solving the above-mentioned problem may be infeasible in some cases due to the large problem size. For the setting of Example 1 with mₛ=19, there are 100 binary unknowns and roughly 28,000 equations. If g is set to 8 in this setting, then the problem is nearly unsolvable since the number of equations increases to approximately 9×10⁷.

Exploiting the following property, however, can dramatically reduce the problem size:

Theorem 1. (Girth Invariance Under Vertical Column Shifts) Shifting each column of B upwards or downwards by any amount does not affect the girth of the LDPC convolutional code.

Theorem 1 holds since the LDPC convolutional code B_{[-∞,∞]} is constructed by repeatedly shifting B by one row. This further implies that to calculate the girth of B_{[-∞,∞]}, it is sufficient to determine only the distances between two non-zero bits in each column of B, instead of their absolute positions. For a formal derivation based on this property, let aᵢ^{(j)} denote the i-th non-zero bit in the j-th column of B for 1≦i≦dᵥ^{(j)} and 1≦j≦c. For example, in the first column of FIG. 7, a₁⁽¹⁾=b₀⁽¹⁾, a₂⁽¹⁾=b₈⁽¹⁾, and a₃⁽¹⁾=b₁₅⁽¹⁾. Let x_{i,k}^{(j)} denote the distance between aᵢ^{(j)} and aₖ^{(j)} for 1≦i<k≦dᵥ^{(j)}. For example, x_{1,2}⁽¹⁾=8, x_{2,3}⁽¹⁾=7, and x_{1,3}⁽¹⁾=15 in FIG. 7. A 4-cycle is made if any two of the distances x_{i,k}⁽ⁱ⁾ are identical. It should be noticed that x_{i,k}^{(j)}+x_{k,l}^{(j)}=x_{i,l}^{(j)} for 1≦i<k<l≦dᵥ^{(j)}, and the syndrome former memory can be determined by

$${m}_{s} = {max}_{i , k , j} [ {x}_{i , k}^{( j )} ] .$$

Using the example of FIG. 7 again, the problem of finding the optimal girth-6 base matrix is hence translated into the following problem.

Problem 1.

Find distinct positive integers x_{i,k}^{(j)} for 1≦i<k≦3 and 1≦j≦5 such that

$${max}_{i , k , j} [ {x}_{i , k}^{( j )} ]$$

is minimized.

Now there are only 10 positive integer unknowns and 95 equations (whereas the previous formulation involved 100 binary unknowns and ˜28,000 equations). Depicted in FIG. 8 are the distance parameters for the example optimal base matrix shown in FIG. 7.

The 15 distance parameters are 15 distinct positive integers from 1 to 15, where the maximum number is the smallest among all possible sets consisting of distinct positive numbers. Depending on the embodiment, the distance parameters might or might not be consecutive. In addition, depending on the embodiment, the distance parameters might or might not start from 1. In the non-limiting example case discussed here, however, the solution to the previous formulation is indeed optimal because the distance parameters do start from 1 and run consecutively. Other than this example solution, all possible optimal base matrices can be enumerated using the method based on Theorem 1.

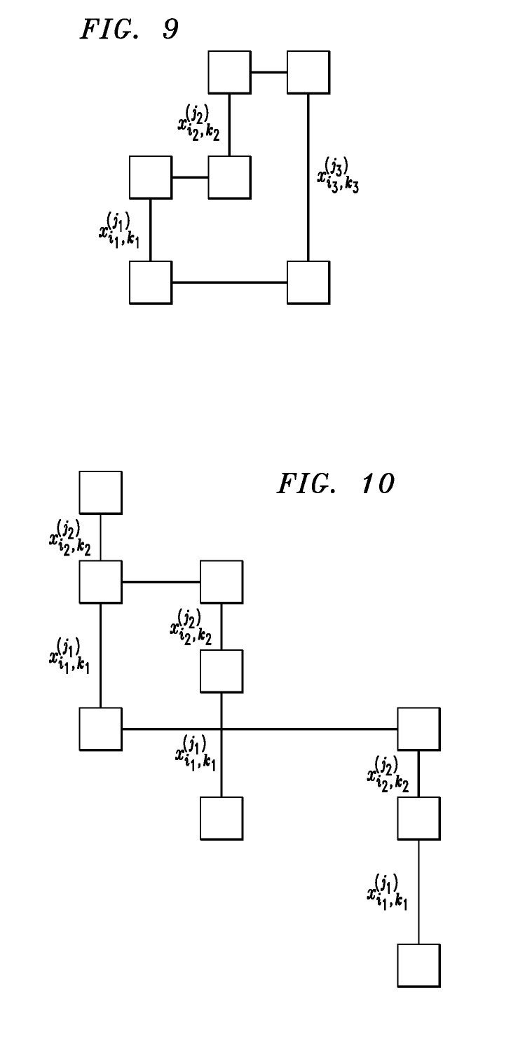

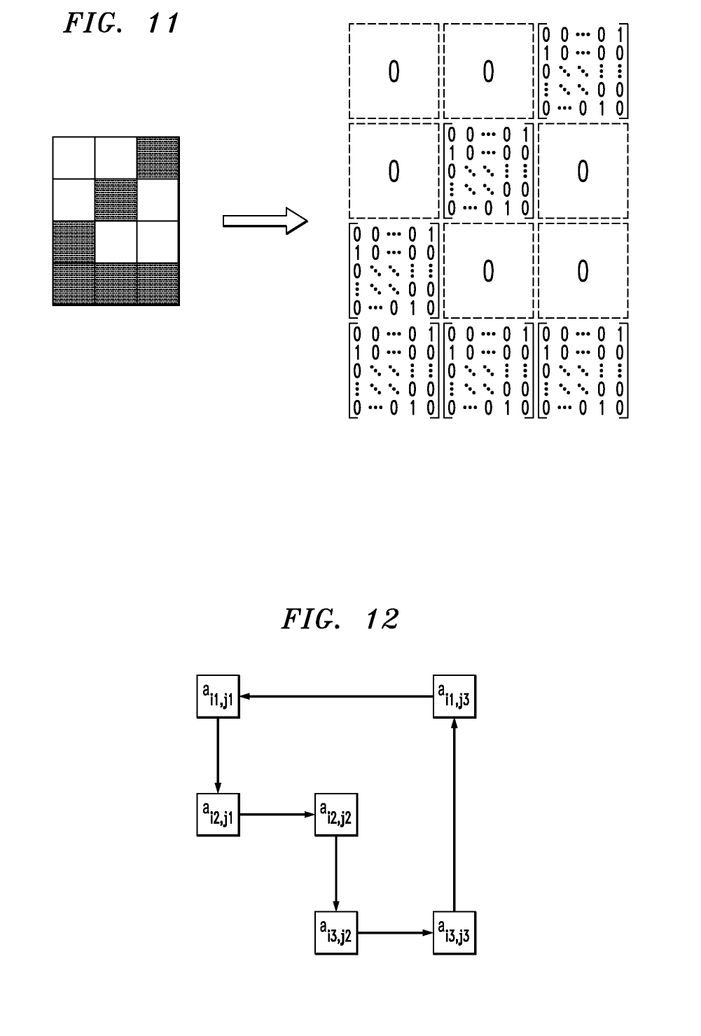

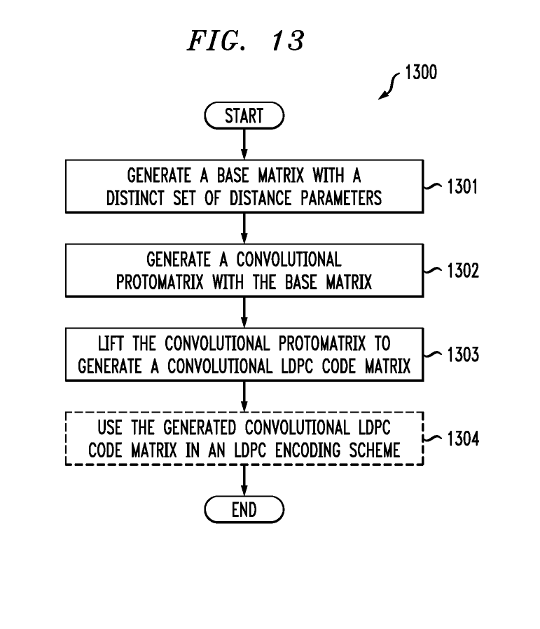

A 6-cycle is made when xᵢ_{₁}_{,k}_{₁}^{(j}^{₁}⁾+xᵢ_{₂}_{,k}_{₂}^{(j}^{₂}⁾=xᵢ_{₃}_{,k}_{₃}^{(j}^{₃}⁾ holds (see FIG. 9), where repetitions are allowed for choosing x_{i,k}^{(j)}. Given the imposed structural constraints, it can be shown that 6-cycles are unavoidable. An example of an unavoidable self-generated 6-cycle is illustrated in FIG. 10, where only two distance parameters construct a 6-cycle with their shifted duplicates.

To cope with this matter, a time-varying base graph or time-varying permutation matrices can be introduced for the lifted code.

### 3. Periodic Quasi-Cyclic Lift of the Base Graph

The base graph obtained by the aforementioned process can be lifted using cyclic permutation matrices to produce a convolutional LDPC code with a much larger girth. For this process, each of the non-zero bits in the base matrix can be replaced with a cyclic permutation matrix as illustrated in FIG. 11.

This approach gives an additional degree of freedom for the code design, namely, the selection of the shifts of the cyclic permutation matrices. From the smallest matrix B (that has been optimized to get a girth-6 code), a matrix A of identical size is generated that is defined as:

$${A}_{i , j} = \{ \begin{matrix}- 1 & if {B}_{i , j} = 0 \\ {a}_{i , j} & if {B}_{i , j} = 1\end{matrix} \qquad ( 16 )$$

where a_{i,j} are integers in the range [0,S) and S is called the lifting factor of the code. The final parity check matrix is obtained by computing a matrix H′ from A where the entries −1 of A are replaced by an all-zero matrix of size S×S, and the other entries are replaced by an identity matrix of size S×S cyclically right-shifted by a_{i,j} positions, or alternatively:

$${( \begin{matrix} & 1 & & & \\ & & 1 & & \\ & & & ⋱ & \\ & & & & 1 \\ 1 & & & & \end{matrix} )}^{{a}_{i , j} - 1 mod S} \qquad ( 17 )$$

The size of H′ is S(mₛ+1)×Sc. The final parity-check matrix of the code is obtained by placing copies of H′ next to each other where each successive copy is moved downwards by S rows. Alternatively, A can be stacked to obtain a convolutional lifting matrix A_{[-∞,∞]}. The goal of the code design is now to select the integers such that the girth of the code is maximized. Conditions for the girth of such lifted codes have been derived in M.P.C. Fossorier, “Quasi-Cyclic Low-Density Parity-Check Codes From Circulant Permutation Matrices,” IEEE Trans. Inform. Theory, August 2004 (the entirety of which is hereby incorporated herein by reference).

Consider the 6-cycle in the matrix A_{[-∞,∞]} illustrated in FIG. 12. The resulting lifted code also has a 6-cycle if and only if the weights fulfill the following condition:

a_{i1,j1}−a_{i2,j1}+a_{i2,j2}−a_{i3,j2}+a_{i3,j3}−a_{i1,j3}≡0 mod S. (18)

If the parameters a_{i,j} are selected such that this condition is not fulfilled, then the 6-cycle is avoided in the final lifted code. However, if there are unavoidable 6-cycles in the final convolutional structure of the matrix, as in this example there are:

a_{9,1}−a_{16,1}+a_{1,1}−a_{9,1}+a_{16,1}−a_{1,1}≡0 mod S, (19)

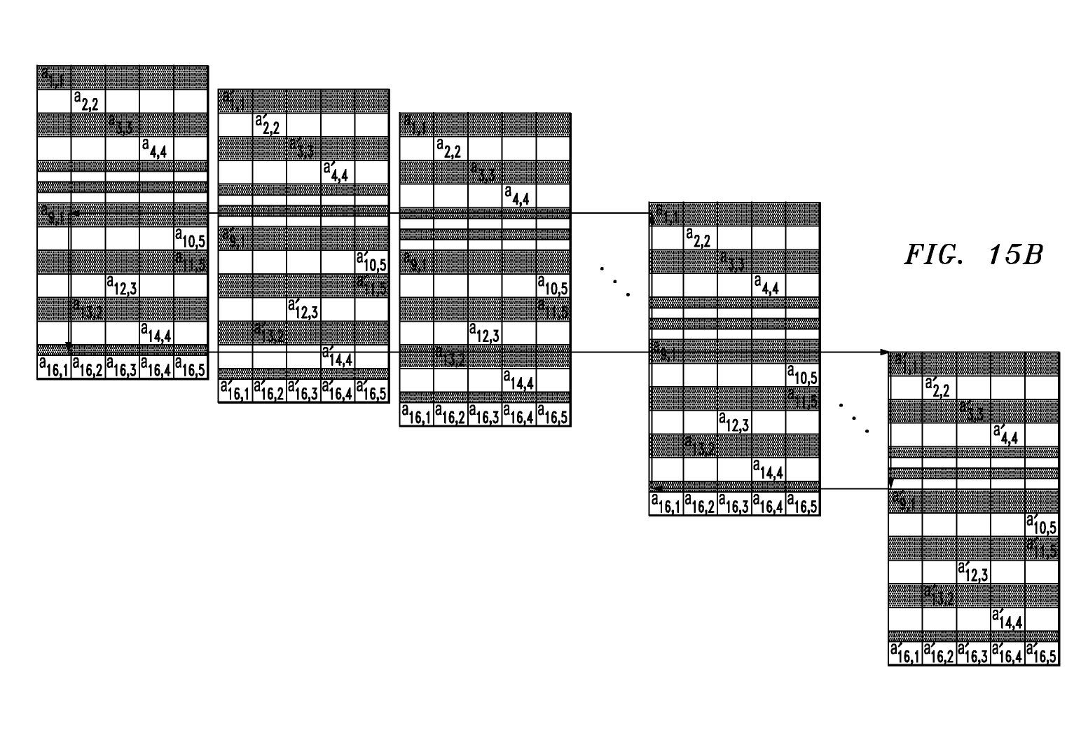

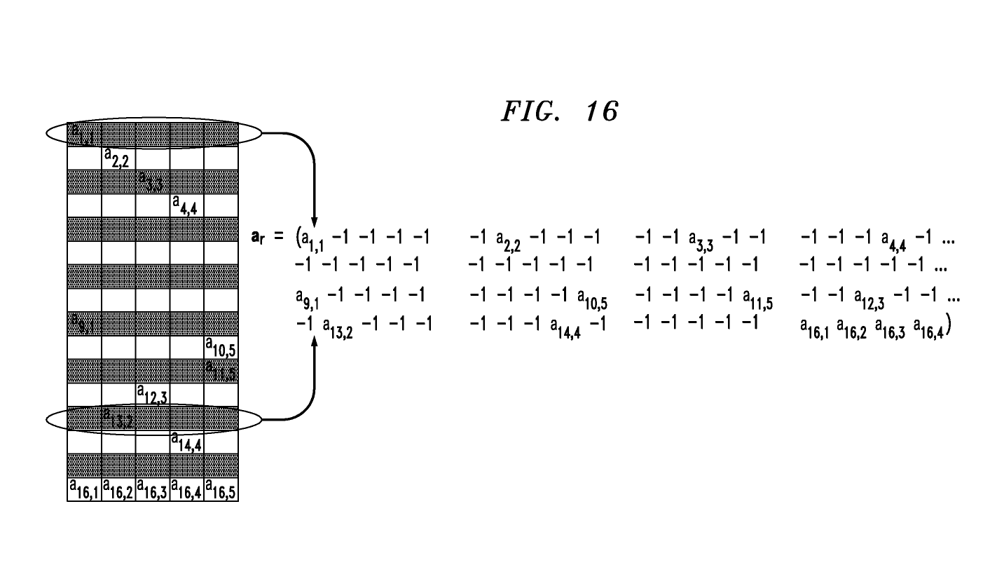

which is always fulfilled, regardless of the values of a_{i,j}. It can be shown that, independently of where the entries a_{i,j} are placed within A, such unavoidable cycles always occur, as illustrated in FIG. 15A.

One way to overcome these unavoidable cycles is to use the same repeating structure element based on the matrix B but to use periodically varying shift values. With a repeating period of P=2, we get the situation illustrated in FIG. 15B, which contains the following condition for 6-cycles:

a_{9,1}−a_{16,1}+a′_{1,1}−a′_{9,1}+a_{16,1}−a_{1,1}=a_{9,1}+a′_{1,1}−a′_{9,1}−a_{1,1}≡0 mod S (20)

Now, however, 4 degrees of freedom arise in selecting a_{9,1}, a′_{9,1}, a′_{1,1} and a_{1,1} in order to avoid 6-cycles. Codes of girth 8 can then be generated as follows:
1) Set the period P=2.
2) Set the column window under consideration to be [1, 2, . . . , cP]+kc where k is some integer offset.
3) Construct the matrix B_{[-∞,∞]} and enumerate all cycles of length 6 that have at least one variable in the window under consideration.
4) For each cycle, evaluate whether one of the resulting equations will always be 0 mod S, regardless of the choice of the values a_{i,j,p}. If such an unsatisfiable cycle equation exists, then increase P←P+1 and return to Step 2), otherwise continue with Step 5)
5) For each cycle enumerated, construct one equation for all i₁, i₂, and j within the cycle, as follows:

Σ(a_{i1,j}−a_{i2,j})≠0 mod S, (21)

These equations (21) can then be put into a matrix G, of size Nc×Pd_{c}, with Nc denoting the total number of cycles of length 6 that were found. A vector a of Pd_{c} elements can now be found such that the remainder of every element of the resulting vector r=Ga is different from 0 when dividing by S; i.e., a single rᵢ and S must be coprime. The vector a can be found, and thus the single a_{i,j} (and a_{i,j}′ etc.), for instance, by casting the problem into a K-SAT problem and using satisfiability solvers, or, if S is a power of 2, using binary field logic or using heuristic methods, e.g., based on differential evolution (the algorithm introduced by K. Price and R. Storn, “Differential Evolution—A Simple and Efficient Heuristic for Global Optimization over Continuous Spaces,” Journal of Global Optimization 11: 341-359, 1997, the teachings of which are incorporated herein by reference).

In order to construct girth-10 codes, the above routine can be modified such that, in Step 3), all cycles of length 8 are also enumerated and a larger equation system is established containing equations to remove 6-cycles and 8-cycles as well. By proper selection of a and the period P, girth-N codes, with N≧10, can be constructed relatively easily.

### 4. Decoding Architecture for the Proposed Scheme

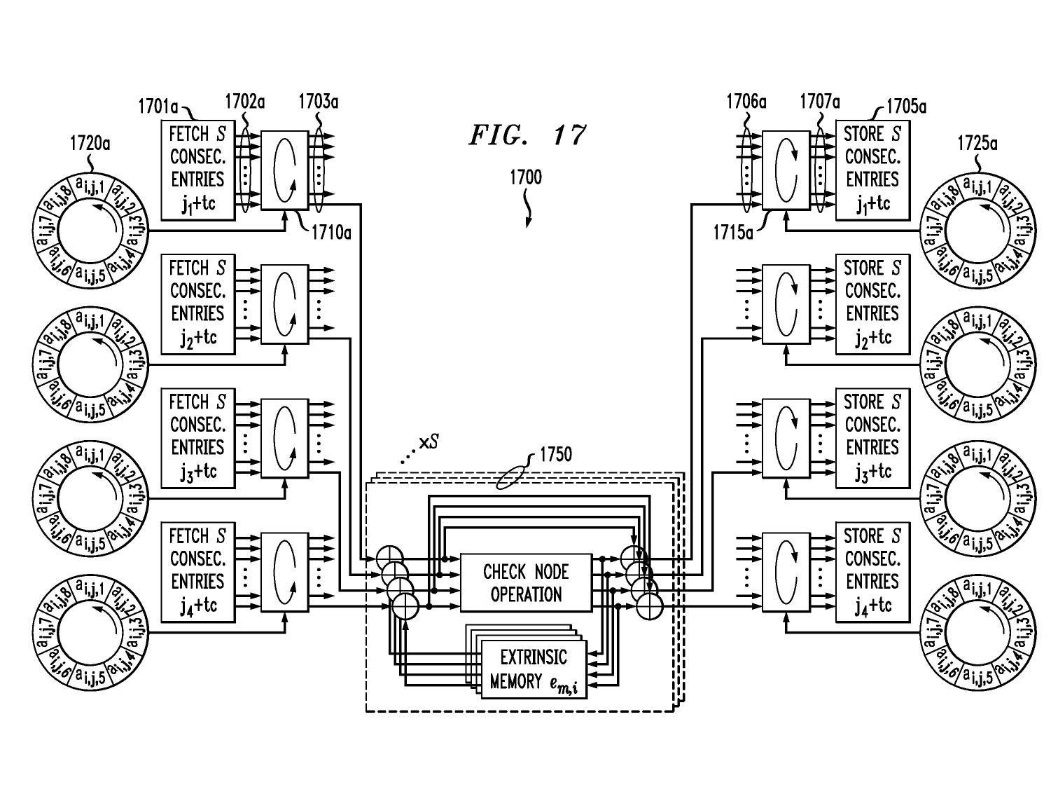

One advantage of the proposed scheme is that the implementation of a decoder can become relatively easy. Sticking with the running example, instead of using a block-based matrix A and placing stacked copies of A next to each other, a row-defining vector aᵣ can be used that is obtained easily from A, in accordance with the derivation illustrated in FIG. 16.

Specifically, an index set of aᵣ is defined as: J={iε[1, . . . , d_{c}]aⱼ≠−1}P, i.e., those positions that are not −1, which denotes a void entry (to be replaced by the S×S zero matrix in the final parity-check matrix). The cardinality of the index set is card(J)=d_{c}. The final convolutional matrix is obtained by stacking copies of aᵣ, shifted by c entries. This can be used to design a very efficient decoder, based on the layered decoding algorithm (D. Hocevar, IEEE SiPS 2004, the teachings of which are incorporated herein by reference). The layered decoding algorithm processes one row of A_{[-∞,∞]} (or S rows of H_{[-∞,∞]}) and is based on an a posteriori memory. With the proposed code construction, the access to the memories can be hard-wired to the positions jᵢ taken from the index set J. The convolutional nature is taken into account by offsetting the memory access by a temporal factor tc, where t is the position in the code and c the number of columns of A. The periodic nature of the cyclic shifts can be taken into account by using programmable barrel-shifted circuits and a cyclic memory storing the cyclic shift values that are rotated whenever t is increased.

An example decoder 1700 is shown in FIG. 17. For simplicity, a largely simplified code with d_{c}=4 is shown for visualization purposes, not the d_{c}=16 case of the prior example. Decoder 1700 processes four sets of S entries each in parallel. For example, fetch circuit 1701a fetches S consecutive entries 1701a corresponding to position j₁+tc. Input barrel shifter 1710a processes the S entries 1701a based on the elements of the row-defining vector aᵣ (see FIG. 16), which are circularly shifted into the barrel shifter from cyclic memory 1720a to form S shifted values 1703a. The S shifted values 1703a are applied in parallel to the S different layers of layered decoding logic 1750, where the layered decoding algorithm is executed (see Hocevar reference supra). Note that each layer of decoding logic 1750 receives a value from each of the four different input barrel shifters of decoder 1700.

The 4S decoded values generated by layered decoding logic 1750 are applied to the four different output barrel shifters of decoder 1700. For example, output barrel shifter 1715a receives S decoded values 1706a, one from each of the S different layers of decoding logic 1750. Analogous to input barrel shifter 1710a, output barrel shifter 1715a processes the S decoded values 1706a based on the elements of the row-defining vector aᵣ, which are circularly shifted into the barrel shifter from cyclic memory 1725a to form S output values 1707a that are stored by store circuit 1705a.

It should be noted that the four fetch circuits and the four store circuits of decoder 1700 can be hardwired since the values jᵢ are determined offline during code construction. No programmable memory access is required for fetch and store operations, thus greatly reducing execution time and hardware components.

Utilizing the salient features of the foregoing discussion, FIG. 13 provides a flowchart diagram illustrating a method 1300 for generating a convolutional LDPC code matrix for use in an LDPC encoding scheme, according to particular embodiments.

Method 1300 may commence in step 1301 wherein a base matrix is generated, such that the base matrix is characterized by a distinct set of distance parameters such that no distance parameter is repeated more than once. Step 1301 is carried out, among particular embodiments, via the techniques identified in connection with Theorem 1 and/or Problem 1, above. That is, the base matrix may be generated by using computer-implemented techniques to generate a set of distance parameters such that no distance parameter is duplicated for the same base graph. The utilized computer-implemented techniques may include various iterative, Monte-Carlo, numeric, and/or algorithmic techniques as are known in the art. According to particular other embodiments, the set of distance parameters may be known in advance, may be stored and/or retrieved in a database, may be provided by a separate computer system and/or user from that of the system performing the rest of method 1300, and/or the like.

Method 1300 may then proceed to step 1302 wherein the base matrix of step 1301 is used to generate a convolutional protomatrix in accordance with the foregoing discussion.

Method 1300 may then proceed to step 1303 wherein the convolutional protomatrix of step 1302 is lifted to generate a convolutional LDPC code matrix in accordance with the foregoing discussion.

Method 1300 may then proceed to optional step 1304 wherein the convolutional LDPC code matrix of step 1303 is used in an LDPC encoding scheme that implements step 1304. Note that the system that implements step 1304 may be different from the computer system(s) that implement steps 1301-1303.

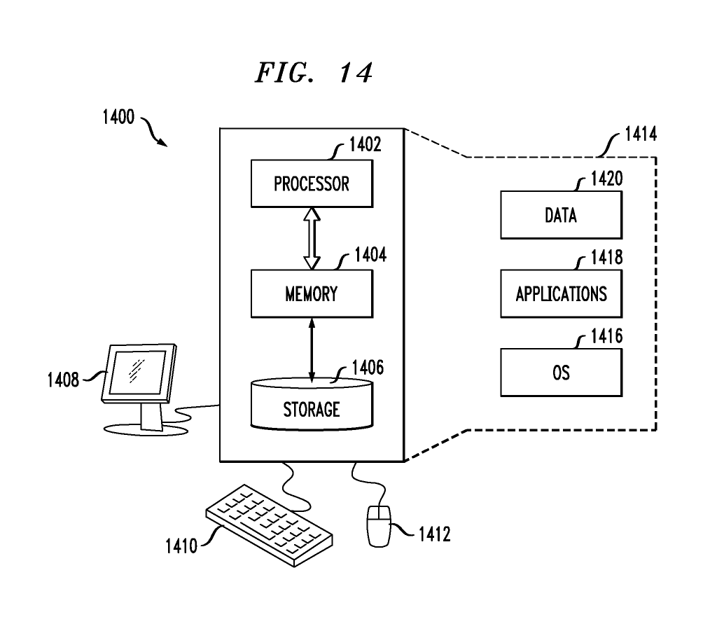

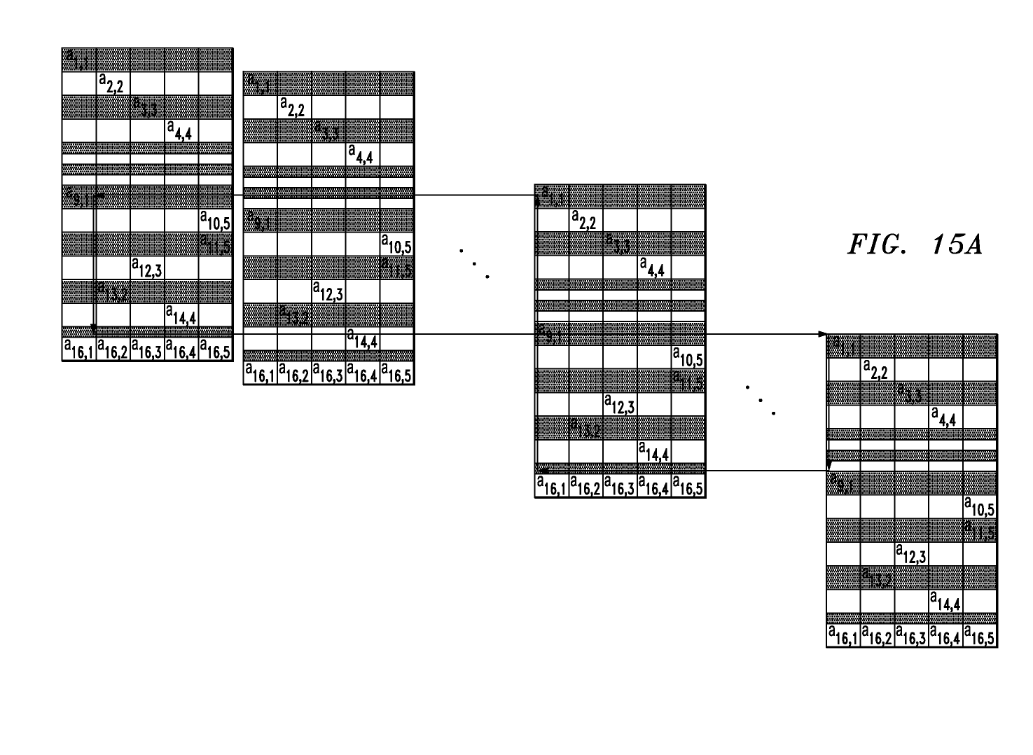

FIG. 14 is a schematic block diagram of an example computer system 1400 for performing some or all of the steps in the methods of the present disclosure described above. The computer system 1400 includes a processor 1402 coupled to a memory 1404 and additional memory or storage 1406 coupled to the memory 1404. The computer system 1400 also includes a display device 1408, input devices 1410 and 1412, and software 1414. The software 1414 includes operating system software 1416, applications programs 1418, and data 1420. When software or a program is executing on the processor 1402, the processor becomes a “means-for” performing the steps or instructions of the software or application code running on the processor 1402. That is, for different instructions and different data associated with the instructions, the internal circuitry of the processor 1402 takes on different states due to different register values, etc., as is known in the art. Thus, any means-for structures described herein relate to the processor 1402 as it performs the steps of the methods disclosed herein.

In one instantiation of computer system 1400, the applications programs 1418 can include, among other things, processors designed to generate a convolutional LDPC code matrix by implementing steps 1301-1303 of FIG. 13. In the same or different instantiation of computer system 1400, the applications programs 1418 can include, among other things, an LDPC encoder and/or decoder that implements step 1304 of FIG. 13, and the data 1420 can include unencoded data to be LDPC encoded, the resulting LDPC-encoded data, and/or corresponding LDPC-decoded data.

Embodiments may be implemented as (analog, digital, or a hybrid of both analog and digital) circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, general-purpose computer, or other processor.

While the example embodiments have been described with respect to processes of circuits, including possible implementation as a single integrated circuit, a multi-chip module, a single card, or a multi-card circuit pack, the invention(s) is/are not so limited. As would be apparent to one skilled in the art, various functions of circuit elements may also be implemented as processing blocks in a software program. Such software may be employed in, for example, a digital signal processor, micro-controller, general purpose computer, or other processor.

Embodiments can be manifest in the form of methods and apparatuses for practicing those methods. Embodiments can also be manifest in the form of program code embodied in tangible media, such as magnetic recording media, optical recording media, solid state memory, floppy diskettes, CD-ROMs, hard drives, or any other non-transitory machine-readable storage medium, wherein, when the program code is loaded into and executed by a machine, such as a computer, the machine becomes an apparatus for practicing the invention(s). Embodiments can also be manifest in the form of program code, for example, stored in a non-transitory machine-readable storage medium including being loaded into and/or executed by a machine, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits

Any suitable processor-usable/readable or computer-usable/readable storage medium may be utilized. The storage medium may be (without limitation) an electronic, magnetic, optical, electromagnetic, infrared, or semiconductor system, apparatus, or device. A more-specific, non-exhaustive list of possible storage media includes a magnetic tape, a portable computer diskette, a hard disk, a random access memory (RAM), a read-only memory (ROM), an erasable programmable read-only memory (EPROM) or Flash memory, a portable compact disc read-only memory (CD-ROM), an optical storage device, and a magnetic storage device. Note that the storage medium could even be paper or another suitable medium upon which the program is printed, since the program can be electronically captured via, for instance, optical scanning of the printing, then compiled, interpreted, or otherwise processed in a suitable manner including but not limited to optical character recognition, if necessary, and then stored in a processor or computer memory. In the context of this disclosure, a suitable storage medium may be any medium that can contain or store a program for use by or in connection with an instruction execution system, apparatus, or device.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments may be made by those skilled in the art without departing from the scope encompassed by the following claims.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the example methods set forth herein are not necessarily required to be performed in the order described, and the order of the steps of such methods should be understood to be merely example. Likewise, additional steps may be included in such methods, and certain steps may be omitted or combined, in methods consistent with the scope of the disclosure.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention(s). The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

What is claimed is:

1. A method for generating a convolutional LDPC code matrix for use in an LDPC coding scheme, the method comprising:
(a) generating, with a processor, a base matrix by constraining the base matrix to have a set of distinct distance parameters in which no distance parameter is repeated;
(b) generating, with the processor, a convolutional protomatrix based on the base matrix; and
(c) lifting, with the processor, the convolutional protomatrix to generate the convolutional LDPC code matrix.

2. The method of claim 1, wherein the base matrix has dimensions of c×mₛ, where c represents a length of a codeword in the LDPC coding scheme, and mₛ comprises a syndrome former memory of the convolutional protomatrix.

3. The method of claim 1, wherein:
bᵢ=[bᵢ⁽¹⁾, . . . , bᵢ^{(c)}] represents column vectors of the base matrix; and
step (a) comprises selecting a matrix from among a set of matrices that simultaneously satisfy the following equations:
$${b}_{i}^{( j )} ∈ \{ 0 , 1 \} , \\ {\sum }_{0 \leq i \leq {m}_{s}} {b}_{i}^{( j )} = {d}_{v} , \\ and$$
$${b}_{i}^{( j )} + {b}_{i + l}^{( j )} + {b}_{i + n}^{( k )} + {b}_{i + l + n}^{( k )} \leq 3 ,$$
where dᵥ is a constant and represents a column degree of the base matrix.

4. The method of claim 3, wherein step (a) comprises selecting a matrix with a dimension corresponding to the syndrome former memory mₛ that is a minimum among the matrices in the set.

5. The method of claim 2, wherein step (a) comprises finding distinct positive integers x_{i,k}^{(j)} for 1≦i<k≦dᵥ and 1≦j≦c, where x_{i,k}^{(j)} is a distance parameter of the base matrix and represents a distance between aᵢ^{(j)} and aₖ^{(j)} for 1≦i<k≦dᵥ, where aᵢ^{(j)} represents an i-th non-zero bit in a j-th column of the base matrix.

6. The method of claim 5, wherein step (a) further comprises finding distinct positive integers x_{i,k}^{(j)} such that
$${A}_{i , j} = \{ \begin{matrix}- 1 & if {B}_{i , j} = 0 \\ {a}_{i , j} & if {B}_{i , j} = {1}^{′}\end{matrix}$$
minimized.

7. The method of claim 1, wherein the convolutional LDPC code matrix has no 4-cycles.

8. The method of claim 1, wherein the convolutional LDPC code matrix has no N-cycles, where N≧6.

9. The method of claim 1, wherein the lifting of step (c) comprises periodic quasi-cyclic lifting.

10. The method of claim 1, wherein step (c) comprises:
(c1) generating a matrix A whose elements A_{i,j} are given by:
$${A}_{i , j} = \{ \begin{matrix}- 1 & if {B}_{i , j} = 0 \\ {a}_{i , j} & if {B}_{i , j} = 1\end{matrix} ,$$
wherein B_{i,j} are elements of the convolutional protomatrix;
(c2) replacing each −1 by an all-zero matrix of dimension S×S; and
(c3) replacing each a_{i,j} with an identity matrix of dimension S×S cyclically right-shifted by a_{i,j} positions, where S is a lifting factor for the LDPC coding scheme.

11. The method of claim 1, further comprising:
(d) using the convolutional LDPC code matrix in a signal-processing system-implemented LDPC coding scheme.

12. The method of claim 11, wherein the signal-processing system comprises an LDPC decoder that utilizes the convolutional LDPC code matrix of step (c).

13. The method of claim 12, wherein the LDPC decoder employs a layered decoder algorithm.

14. The method of claim 12 wherein, the LDPC decoder utilizes programmable barrel-shifted circuits and a cyclic memory storing cyclic shift values that are rotated periodically over time.

15. A computer program product embedded in a non-transitory medium and comprising computer-readable instructions that, when executed by a suitable computer, cause the computer to perform a method for generating a convolutional LDPC code matrix for use in an LDPC coding scheme, the method comprising:
(a) generating a base matrix by constraining the base matrix to have a set of distinct distance parameters in which no distance parameter is repeated;
(b) generating a convolutional protomatrix based on the base matrix; and
(c) lifting the convolutional protomatrix to generate the convolutional LDPC code matrix.

16. A signal-processing system that implements the LDPC coding scheme of claim 1 using the convolutional LDPC code matrix of claim 1.
